(19) United States
(12) Patent Application Publication
(10) Pub. No.: US 2012/0261641 A1
(43) Pub. Date: Oct. 18, 2012

(54) SEMICONDUCTOR LIGHT EMITTING DEVICE

(75) Inventor: Akira Tanaka, Kanagawa-ken (JP)

(73) Assignee: KABUSHIKI KAISHA TOSHIBA, Tokyo (JP)

(21) Appl. No.: 13/233,375

(22) Filed: Sep. 15, 2011

(30) Foreign Application Priority Data
Apr. 18, 2011 (JP) 2011-092486

(51) Int. Cl. H01L 33/06

(52) U.S. Cl. 257/13; 257/E33.008

(57) ABSTRACT

According to an embodiment, a semiconductor light emitting device includes a stacked body including a first semiconductor layer of a first conductivity type, a second semiconductor layer of a second conductivity type different from the first conductivity type, and a light emitting layer provided between the first semiconductor layer and the second semiconductor layer. A transparent electrode is provided on a first major surface of the stacked body on a side of the first semiconductor layer, the transparent electrode having a thin part, a first thick part thicker than the thin part, and a plurality of second thick parts thicker than the thin part and extending along the first major surface from the first thick part. A first electrode is provided on the first thick part; and a second electrode is electrically connected to the second semiconductor layer.

### CROSS-REFERENCE TO RELATED APPLICATIONS

This application is based upon and claims the benefit of priority from Japanese Patent Application No. 2011-92486, filed on Apr. 18, 2011; the entire contents of which are incorporated herein by reference.

### FIELD

Embodiments are generally related to a semiconductor light emitting device.

### BACKGROUND

In recent years, semiconductor light emitting devices have been widely used in fields of lighting equipment, displays, and the like, and have been required to be improved in light output. For example, a light emitting diode (LED), as one of the semiconductor light emitting devices, has a transparent electrode for current spread and light extraction on a light emitting face, thereby achieving improvement in light output.

Meanwhile, the semiconductor light emitting devices are greatly expected to reduce power consumption. Accordingly, it is desired that the semiconductor light emitting devices are not only improved in light output but also enhanced in light emission efficiency.

### BRIEF DESCRIPTION OF THE DRAWINGS

FIGS. 1A and 1B are schematic views illustrating a semiconductor light emitting device according to a first embodiment;

FIG. 2 is a schematic view illustrating a characteristic of the semiconductor light emitting device according to the first embodiment;

FIG. 3 is a schematic view illustrating a detailed cross-sectional structure of the semiconductor light emitting device according to the first embodiment;

FIGS. 4A and 4B are schematic views of a semiconductor light emitting device according to a second embodiment.

FIGS. 5A to 7B are cross-sectional views illustrating manufacturing processes of the semiconductor light emitting device according to the second embodiment;

FIGS. 8A and 8B are schematic plan views illustrating a semiconductor light emitting device according to a variation of the second embodiment.

### DETAILED DESCRIPTION

In general, according to an embodiment, a semiconductor light emitting device includes a stacked body including a first semiconductor layer of a first conductivity type, a second semiconductor layer of a second conductivity type different from the first conductivity type, and a light emitting layer provided between the first semiconductor layer and the second semiconductor layer. A transparent electrode is provided on a first major surface of the stacked body on a side of the first semiconductor layer, the transparent electrode having a thin part, a first thick part thicker than the thin part, and a plurality of second thick parts thicker than the thin part and extending along the first major surface from the first thick part. A first electrode is provided on the first thick part; and a second electrode is electrically connected to the second semiconductor layer.

Embodiments will now be described with reference to the drawings. Throughout the drawings, identical components are marked with identical reference numerals, and detailed descriptions thereof are omitted as appropriate in the specification of the application.

### First Embodiment

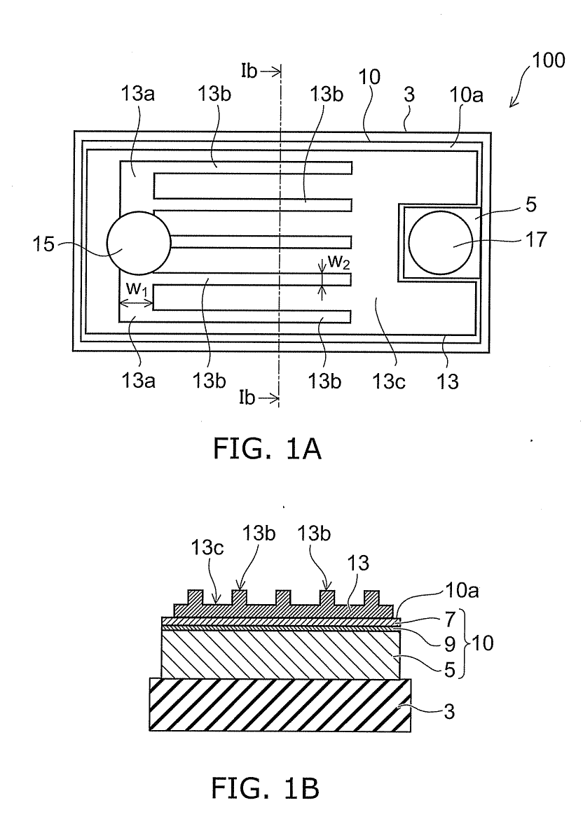

FIGS. 1A and 1B are schematic views of a semiconductor light emitting device 100 according to a first embodiment. The semiconductor light emitting device 100 is a blue LED made of a nitride semiconductor, for example, and FIG. 1A is a schematic plan view of its chip face. FIG. 1B is a cross sectional view showing a cross section taken along a line Ib-Ib in FIG. 1A.

As shown in FIGS. 1A and 1B, the semiconductor light emitting device 100 includes a stacked body 10 provided on a sapphire substrate 3, for example. In addition, as shown in FIG. 1A, the stacked body 10 is provided in a rectangular shape with a long side and a short side, in a planar view parallel to a light emitting face 10a as a first major surface of the stacked body 10.

The light emitting face 10a is provided with a transparent electrode 13. The transparent electrode 13 has a thin part 13c, a first thick part 13a thicker than the thin part 13c, and a second stripe-shaped thick part 13b that is thicker than the thin part 13c and extends from the first thick part 13a along the light emitting face 10a.

In the embodiment, as shown in FIGS. 1A and 1B, a longitudinal direction of the first thick part 13a corresponds to a short-side direction of the rectangular light emitting face 10a, and a longitudinal direction of the second thick part 13b corresponds to the long-side direction of the light emitting face 10a. In addition, a thickness of the second thick part 13b and a thickness of the first thick part 13a are the same.

The same thickness here is not limited to an identical thickness in a strict sense. For example, there may a difference in thickness between the thick part 13a and the thick part 13b, resulting from a thickness distribution of the transparent electrode 13 except for the thin part 13c.

As shown in FIG. 1A, the semiconductor light emitting device 100 includes a p electrode 15 as a first electrode and an n electrode 17 as a second electrode, and emits light from the light emitting face 10a when a drive current flows from the p electrode 15 to the n electrode 17. The p electrode 15 is provided on the thick part 13a and is electrically connected to the transparent electrode 13. The n electrode 17 is provided on a surface of an n-type clad layer 5 exposed in the chip face, and is electrically connected to the n-type clad layer 5.

Meanwhile, as shown in FIG. 1B, the stacked body 10 has a p-type clad layer 7 as a first semiconductor layer, the n-type clad layer 5 as a second semiconductor layer, and a light emitting layer 9 provided between the p-type clad layer 7 and the n-type clad layer 5. Light emitted from the light emitting layer 9 is mainly extracted from the light emitting face 10a as a surface of the p-type clad layer 7. In addition, as shown in FIG. 1B, the light emitting face 10a constitutes the surface of the p-type clad layer 7 and also the first major surface of the stacked body 10.

The transparent electrode 13 made of indium tin oxide (ITO), for example, is provided on the surface of the light emitting face 10a. As described above, the transparent electrode 13 is provided with the thick part 13b, and the thin part 13c that is thinner than the thick part 13b in a direction perpendicular to the light emitting face 10a.

ITO is a conductive film that lets visible light pass through, and has a sheet resistance higher than sheet resistances of metal films, such as gold (Au), aluminum (Al), and the like. Therefore, as shown in the embodiment, formation of the thick parts 13a and 13b and the thin part 13c on the transparent electrode 13 makes differences in electric resistance significant for the driving current flow. Accordingly, an electric current to be injected into the light emitting layer 9 through the thick part 13b, can be made larger than an electric current injected into the light emitting layer 9 through the thin part 13c.

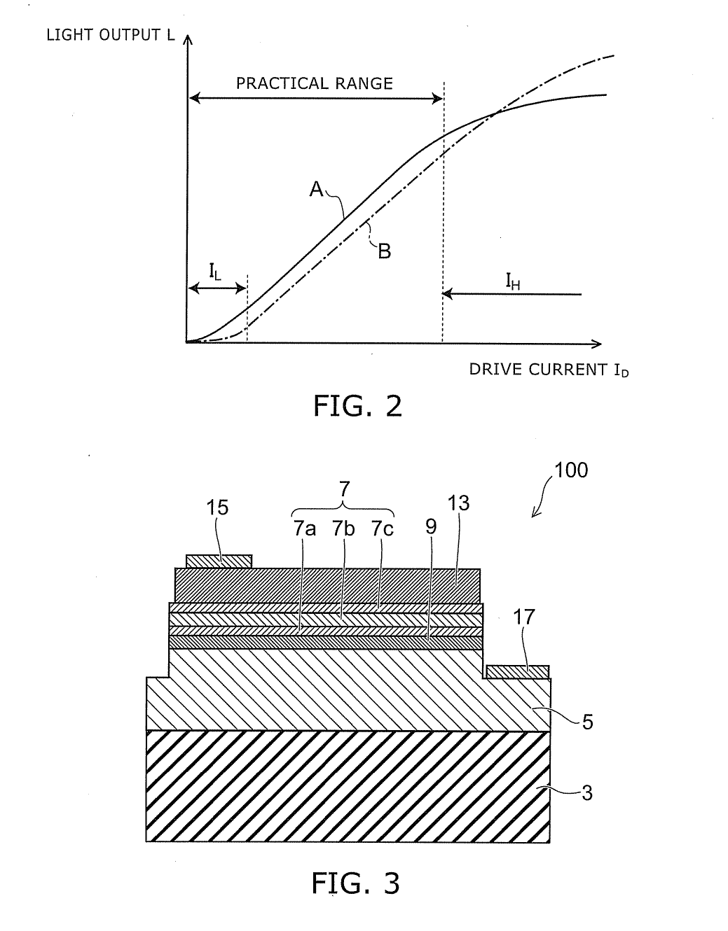

FIG. 2 is a graph schematically showing characteristics of the semiconductor light emitting device 100, where a horizontal axis shows a drive current I and a vertical axis shows a light output L.

In FIG. 2, graph A shows I-L characteristics of the semiconductor light emitting device 100, and graph B shows I-L characteristics of a semiconductor light emitting device according to a comparative example (not shown). The semiconductor light emitting device according to the comparative example is different from the semiconductor light emitting device 100, in that the thick parts 13a and 13b are not provided and the transparent electrode 13 has a uniform thickness.

If the transparent electrode 13 of a uniform thickness is formed on an entire face of the light emitting face 10a, a drive current spreads over the entire face of the light emitting face 10a and is injected into the light emitting layer 9. Accordingly, the entire light emitting layer 9 emits light uniformly, and exhibits the I-L characteristics of the graph B, for example.

The light output L shown in the graph B increases monotonously with increase in the drive current I_{D}. However, the increase rate of the light output L to the drive current I_{D}, is small with low light emission efficiency, in a low injection region I_{L} with the smaller drive current I_{D}. When the drive current flows beyond the low injection region I_{L}, the increase rate of the light output L becomes higher with improvement in light emission efficiency.

Further, as the drive current I_{D} is increased to reach a high injection region I_{H}, the light output L shows a saturation tendency. For example, considering life time and controllability of the semiconductor light emitting device, it may be used in a practical range where the drive current I_{D} is smaller than in the high injection region I_{H}.

In contrast to this, in the semiconductor light emitting device 100, the increase rate of light output is improved from the low injection region I_{L}, and higher output is provided in the practical range, as compared with the comparative example. This advantage will be described as below.

Carriers (electrons and holes) injected by the drive current I_{D} into the light emitting layer 9 include ones that recombine with light emission and ones that recombine through a non-light emission process. For example, a Shockley-Read-Hall (SRH) process is known as non-light emission processes, where the carriers recombine through a deep level in a bandgap. If a small number of carriers are injected into the light emitting layer 9, such non-light emitting recombination occurs at a high rate. Since the number of deep levels—contributing to the non-light emitting recombination is limited, the rate of light emitting recombination becomes higher with a larger number of carriers. Thereby it is possible to improve the light emission efficiency. Accordingly, the I-L characteristics as shown in the graph B are exhibited.

Meanwhile, in the semiconductor light emitting device 100, a larger amount of the drive current I_{D} flows through the thick parts 13a and 13b of the transparent electrode 13, and therefore the density of carriers in the light emitting layer 9 becomes higher at portions under the thick parts 13a and 13b than at a portion under the thin part 13c. As a result, the portions of the light emitting face 10a provided with the thick parts 13a and 13b actively contribute to light emission.

That is, in the semiconductor light emitting device 100, a light emitting region is substantively narrowed to raise the density of carriers in the low injection region I_{L}. This decreases the rate of non-light emitting recombination, and improves light emission efficiency as compared with the comparative example.

Meanwhile, in the high injection region I_{H} with the larger drive current I_{D}, the density of carriers in the light emitting layer 9 under the thick parts 13a and 13b of the semiconductor light emitting device 100 becomes higher than the density of carriers in the comparative example. Therefore, current loss increases due to an overflow of electrons flowing from the light emitting layer 9 to the p-type clad layer 7, an Auger effect, or the like, thereby resulting in a significant saturation tendency of the light output L. As a result, the light output L of the semiconductor light emitting device 100 in the high injection region I_{H} becomes lower than the comparative example, but does not cause any problem in practical use as far as the light output L exceeds the comparative example, in the practical range of the drive current I_{D}.

For example, if the transparent electrode 13 is removed from the thin part 13c, it is possible to increase current flowing through the thick parts 13a and 13b and further improve light emission efficiency in the low injection region I_{L}. In this case, however, the density of electrons and holes in the light emitting layer 9 under the thick parts 13a and 13b excessively increases, and thereby an overflow of electrons is prone to occur, for example. Accordingly, the light output L exhibits a saturation tendency from the region with the lower drive current I_{D}, which may make the light output lower than in the comparative example, in the practical range. Therefore, the semiconductor light emitting device 100 has the thin part 13c retained to suppress excessive current concentration in the thick parts 13a and 13b.

Further, current flows into the light emitting layer 9 through the thin part 13c, thereby suppressing light absorption in the light emitting layer 9. That is, the light emitting layer 9 with the lower carrier density functions as a light emission absorber. Therefore, retaining the thin part 13c for injection of carriers into the light emitting layer 9 thereunder also makes it possible to suppress light absorption and improve light emission efficiency.

In addition, to avoid excessive current concentration in the thick parts 13a and 13b, the stripe-shaped thick part 13b desirably extends to the entire face of the light emitting face 10a, or to a wide region of the light emitting face 10a. For example, in the example shown in FIG. 1A, the square thick part 13a extending in a direction along the short side of the light emitting face 10a and a plurality of thick parts 13b extending from the thick part 13a in a direction along the long side of the light emitting face 10a, are provided to allow a wide central region of the light emitting face 10a to emit light evenly.

Further, in a plane parallel to the light emitting face 10a, for example, a maximum width W₂ orthogonal to an extending direction of the thick part 13b is made smaller than a minimum width W₁ of the thick part 13a. This allows the drive current I_{D} injected from the p electrode 15 to spread uniformly over the entire thick part 13a with low sheet resistance and flow evenly into the plurality of the thick parts 13b. As a result, it is possible to avoid local current concentration and improve light emission efficiency and light output.

In addition, as shown in FIGS. 1A and 1B, the transparent electrode 13 is provided inside an outer edge of the light emitting face 10a. That is, the transparent electrode 13 is not provided at a portion along the outer edge of the light emitting face 10a. For example, surface defects exist in high density on side faces of the stacked body 10. Accordingly, if a drive current flows into the outer edge of the stacked body 10, non-light emitting recombination increasingly occurs with lower light emission efficiency. Therefore, when the transparent electrode 13 is not provided at a portion along the outer edge of the light emitting face 10a, it is possible to suppress a drive current flowing into the outer edge of the stacked body 10 and avoid reduction in light emission efficiency.

FIG. 3 is a schematic view of a detailed cross-sectional structure of the semiconductor light emitting device 100. As described above, the semiconductor light emitting device 100 is a blue LED made of a nitride semiconductor formed on the sapphire substrate 3.

The semiconductor light emitting device 100 includes the n-type clad layer 5, the light emitting layer 9, and the p-type clad layer 7, which are provided on the sapphire substrate 3. For example, the n-type clad layer 5 is an n-type GaN layer with a thickness of 2.0 μm. The light emitting layer 9 has a multiple quantum well (MQW) structure in which In_{0.2}Ga_{0.8}N layers and In_{0.05}Ga_{0.95}N layers are alternately stacked. The MQW structure includes eight quantum wells, for example, which are each formed by 2.5 nm-thick well layers (In_{0.2}Ga_{0.8}N layers) and 10 nm-thick barrier layers (In_{0.05}Ga_{0.95}N layers) sandwiching the well layers.

The p-type clad layer 7 includes a carrier block layer 7a formed by a 10 nm-thick p-type Al_{0.15}Ga_{0.85}N layer for preventing electrons from overflowing from the light emitting layer 9, and a 40 nm-thick p-type GaN layer 7b, and a 5 nm-thick contact layer 7c, which are stacked from the light emitting layer 9 side, for example.

The transparent electrode 13 is provided on the p-type clad layer 7. The transparent electrode 13 may use an ITO film, a zinc oxide (ZnO) film, or a tin oxide (Sn₂O) film, for example. The transparent electrode 13 is provided with a thickness of 400 nm, for example. In addition, a surface of the transparent electrode 13 is etched in a predetermined pattern, thereby to form the thick parts 13a and 13b of a thickness of 400 nm, and the thin part 13c of a thickness of 200 nm. Alternatively, the thickness of the thin part may be not more than 200 nm.

The contact layer 7c as an uppermost layer of the p-type clad layer 7 is a p-type GaN layer in which Mg as a p-type impurity is doped with high concentration, for example, and is provided to lower a contact resistance between the transparent electrode 13 and the p-type clad layer 7.

The p electrode 15 is provided on the thick part 13a of the transparent electrode 13. In addition, the p-type clad layer 7 and the light emitting layer 9 are selectively etched to define the light emitting face 10a as the first major surface of the stacked body 10. Further, the n electrode 17 is provided on the surface of the n-type clad layer 5 exposed by etching the p-type clad layer 7 and the light emitting layer 9.

The foregoing configuration of the semiconductor light emitting device 100 is merely an example, and may be modified in various manners. For example, instead of the sapphire substrate 3, a silicon substrate, an SIC substrate, a GaN substrate, or the like, may be used. In addition, a superlattice buffer layer may be inserted into between the n-type clad layer 5 and the light emitting layer 9, for example.

### Second Embodiment

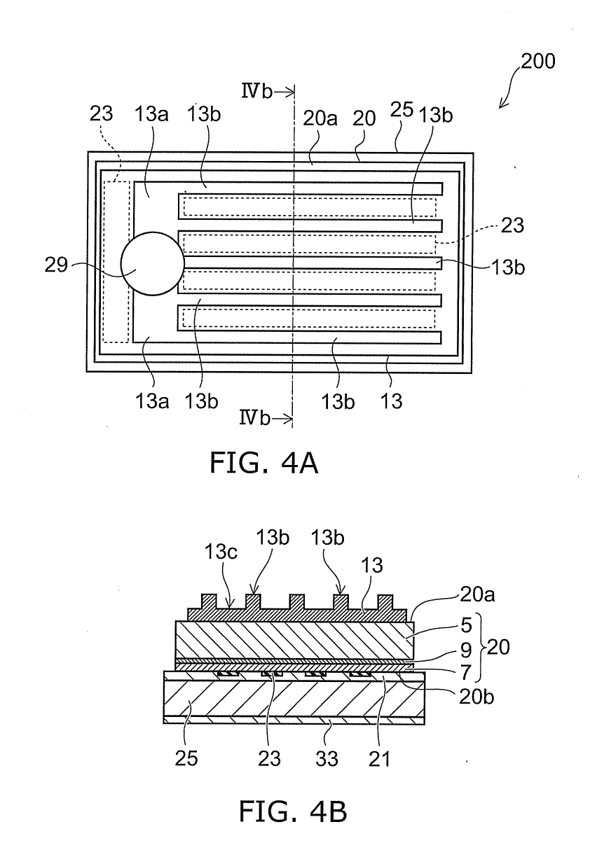

FIGS. 4A and 4B are schematic views of a semiconductor light emitting device 200 according to a second embodiment. FIG. 4A is a plan view of a chip face of the semiconductor light emitting device 200. FIG. 4B is a schematic view of a cross section taken along a line IVb-IVb in FIG. 4A.

As shown in FIG. 4A, in the semiconductor light emitting device 200, a transparent electrode 13 is provided on a light emitting face 20a as a first major surface of a stacked body 20. The transparent electrode 13 has a first thick part 13a, and a second thick part 13b extending in a stripe shape from the first thick part 13a. An n electrode 29 as a first electrode is provided on the first thick part 13a.

For example, the thick part 13a is provided in the shape of a rectangle extending along a short side of the light emitting face 20a, and the thick part 13b extends in a stripe shape along a long side of the light emitting face 20a. In addition, a plurality of thick parts 13b extend to near an outer edge of the light emitting face 20a to allow the light emitting face 20a to emit light evenly. Further, the transparent electrode 13 is provided inside the outer edge of the light emitting face 20a.

As shown in FIG. 4B, the stacked body 20 in the embodiment is provided on a support substrate 25 via a p electrode 21 as a second electrode. The stacked body 20 has an n-type clad layer 5 as a first semiconductor layer, a p-type clad layer 7 as a second semiconductor layer, and a light emitting layer 9 provided between the n-type clad layer 5 and the p-type clad layer 7.

The transparent electrode 13 is provided on the light emitting face 20a as the first major surface of the stacked body 20 and a surface of the n-type clad layer 5. The transparent electrode 13 has the thick part 13b relatively thicker in a direction perpendicular to the light emitting face 20a, and a thin part 13c thinner than the thick part 13b.

The semiconductor light emitting device 200 is configured in such a manner that the p electrode 21 is provided on a second major surface 20b of the stacked body 20 and a drive current flows from the p electrode 21 to the transparent electrode 13 provided on the first major surface 20a, thereby emitting light from the light emitting layer 9.

The p electrode 21 is provided so as to reflect the light emitted from the light emitting layer 9 in a direction toward the light emitting face 20a. For example, the p electrode 21 can contain silver (Ag) or gold (Au) at a portion near the p-type clad layer 7, thereby reflecting blue light emitted from the light emitting layer 9.

A current blocking layer 23 is provided between the p electrode 21 and the p-type clad layer 7. As shown in FIG. 4A, the thick part 13b has portions not overlapping the current blocking layer 23, in a planar view parallel to the light emitting face 20a. Accordingly, a straight current path from the thin part 13c toward the p electrode 21 is blocked to concentrate a drive current on portions of the light emitting layer 9 under the thick part 13b.

Further, a current blocking layer can also be provided under the n electrode 29 to suppress light emission from the light emitting layer 9 under the n electrode 29, in order to improve the light emission efficiency.

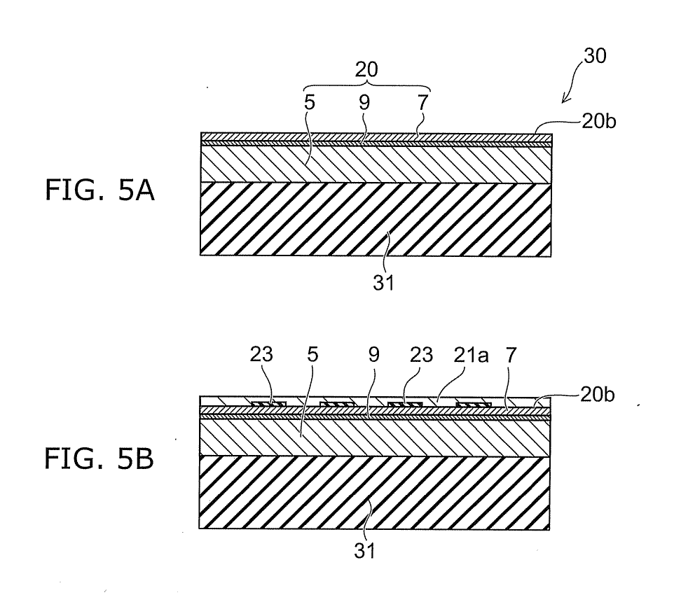

Next, a procedure for manufacturing the semiconductor light emitting device 200 will be described with reference to FIGS. 5A to 7B. FIGS. 5A to 7B show schematically a cross section of a wafer in each process.

First, as shown in FIG. 5A, the n-type clad layer 5, the light emitting layer 9, the p-type clad layer 7 are grown in sequence to form the stacked body 20 on the sapphire substrate 31. These layers can be formed using a metal organic chemical vapor deposition (MOCVD) method, for example. Detailed configurations of the layers are the same as in the semiconductor light emitting device 100 shown in FIG. 3.

Next, as shown in FIG. 5B, the current blocking layer 23 and the p electrode 21a are formed on the second major surface 20b of the stacked body 20. The current blocking layer 23 may use a silicon oxide film (SiO₂ film) formed by a chemical vapor deposition (CVD) method, for example. The p electrode 21a may use a multilayer film in which nickel (Ni), Ag, platinum (Pt), and Au are stacked in sequence from the p-type clad layer 7 side, for example.

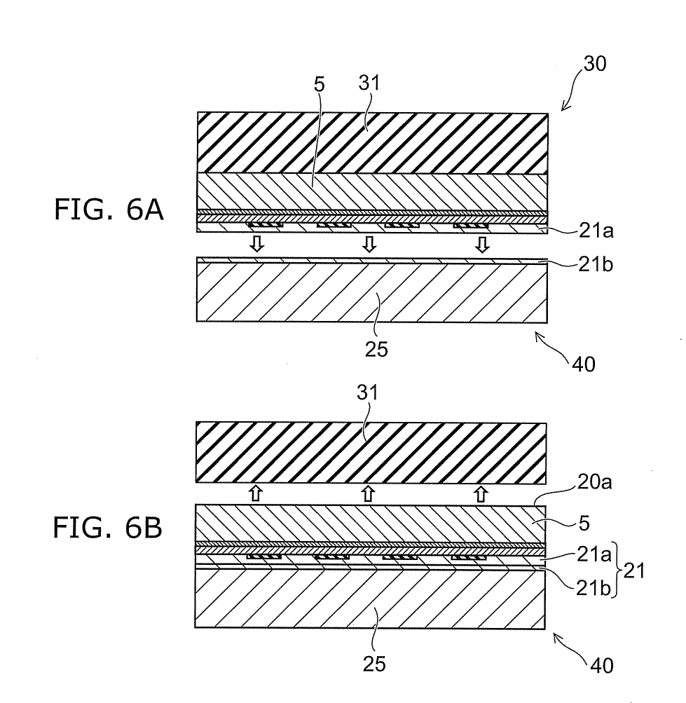

Next, as shown in FIG. 6A, a wafer 30 with the stacked body 20 and the p electrode 21a, and a wafer 40 with the p electrode 21b formed on a surface of the support substrate 25, are bonded to each other. The support substrate 25 may be a p-type silicon substrate or a p-type germanium substrate, for example. The p electrode 21b contains Au, for example. In addition, as shown in FIG. 6A, a surface of the p electrode 21a and a surface of the p electrode 21b are brought into contact, and the two wafers are subjected to weight bearing from a back side, and thereby the p electrode 21a and the p electrode 21b are bonded to form the p electrode 21.

Then, a YAG laser, for example, is irradiated to the wafer 30 from the back side to dissociate partial crystal from the n-type clad layer 5, thereby to separate the sapphire substrate 31 from the n-type clad layer 5, as shown in FIG. 6B.

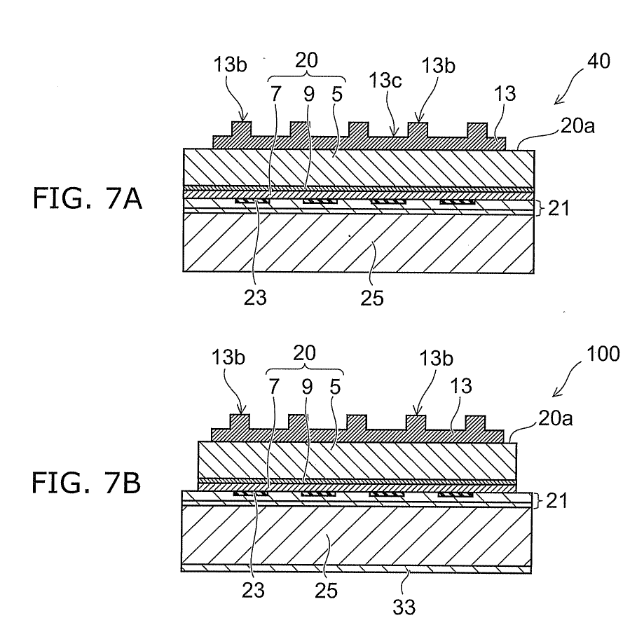

Next, as shown in FIG. 7A, the transparent electrode 13 is formed on the first major surface 20a of the stacked body 20 exposed by separating the sapphire substrate 31. The transparent electrode 13 uses an ITO film formed on the surface of the first major surface 20a by a sputtering method, for example. A thickness of the ITO film is about 400 nm, for example.

Subsequently, a surface of the ITO film is selectively etched to form the thick parts 13a and 13b and the thin part 13c. A thickness of the thick parts 13a and 13b is 400 nm that is same as the thickness of the ITO film, for example. A thickness of the thin part 13c is 200 nm, for example. Further, the n electrode 29 is formed on a surface of the thick part 13a (see FIG. 4A). The n electrode may use a multilayer film in which Ni and Au are stacked from the transparent electrode 13 side, for example.

Next, the stacked body 20 is selectively etched to define the light emitting face 20a. Then, a bonding electrode 33 is formed on the back face of the support substrate 25. The wafers are diced into individual chips, thereby completing the semiconductor light emitting device 200.

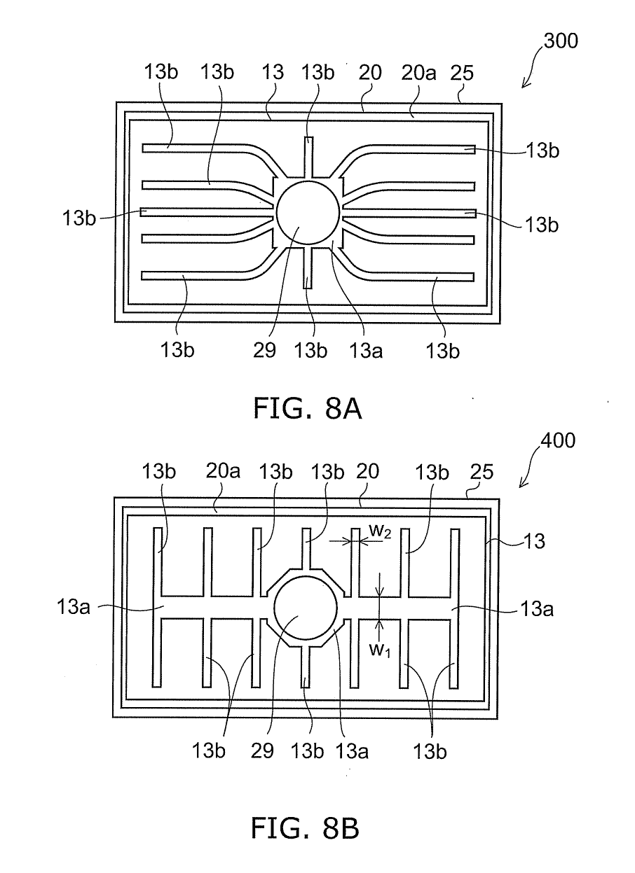

FIGS. 8A and 8B are schematic views of chip faces of semiconductor light emitting devices 300 and 400 according to modification examples of the second embodiment.

For example, in the semiconductor light emitting device 300 shown in FIG. 8A, a first thick part 13a is provided in a center of the chip face, and a second thick part 13b is extended toward an outer edge of the light emitting face 20a.

The semiconductor light emitting device 300 includes a rectangular stacked body 20 with a long side and a short side, in a planar view parallel to the light emitting face 20a as a first major surface. In addition, the first thick part 13a is provided in a region including a center of the rectangle. The second thick part 13b extends from the thick part 13a in a long side direction and in a short side direction of the rectangle. Accordingly, the light emitting face 20a with the n electrode 29 excluded can emit light evenly.

Alternatively, as in the semiconductor light emitting device 400 shown in FIG. 8B, the first thick part 13a may extend from the center of the light emitting face 20a along the long side, and the second thick part 13b may extend from the first thick part 13a toward the outer edge of the light emitting face 20a.

That is, as shown in FIG. 8B, the semiconductor light emitting device 400 also includes a rectangular stacked body 20 with a long side and a short side, in a planar view parallel to the light emitting face 20a. In addition, the first thick part 13a has a region including a center of the rectangle and portions extending from the region including the center in the long side direction of the rectangle. The second thick part 13b has portions extending in the short side direction of the rectangle from the region including the center of the rectangle of the thick part 13a, and portions extending from the portions extending in the long side direction of the rectangle in the thick part 13a, in the short side direction of the rectangle.

In this case, too, a minimum width W1 of the thick part 13a is made larger than a width W2 orthogonal to an extending direction of the thick part 13b. Accordingly, the light emitting layer 9 under the plurality of thick parts 13b can emit light evenly.

The thick parts 13a and 13b shown in FIGS. 8A and 8B and similar shapes can also be provided in the semiconductor light emitting device 100 according to the first embodiment.

In the second embodiment, the first conductivity type is n type and the second conductivity type is p type. Meanwhile, in the first embodiment described above, the first conductivity type is p type and the second conductivity type is n type. However, the conductivity types are not limited to the foregoing embodiments, but reversed conductivity types may be used for each of the embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

The “nitride semiconductor” referred to herein includes group III-V compound semiconductors of BₓIn_{y}Al_{z}Ga_{1-x-y-z}N (0≦x≦1, 0≦y≦1, 0≦z≦1, 0≦x+y+z≦1), and also includes mixed crystals containing a group V element besides N (nitrogen), such as phosphorus (P) and arsenic (As). Furthermore, the “nitride semiconductor” also includes those further containing various elements added to control various material properties such as conductivity type, and those further containing various unintended elements.

What is claimed is:

1. A semiconductor light emitting device, comprising:
a stacked body including a first semiconductor layer of a first conductivity type, a second semiconductor layer of a second conductivity type different from the first conductivity type, and a light emitting layer provided between the first semiconductor layer and the second semiconductor layer;
a transparent electrode provided on a first major surface of the stacked body on a side of the first semiconductor layer, the transparent electrode having a thin part, a first thick part thicker than the thin part, and a plurality of second thick parts thicker than the thin part and extending along the first major surface from the first thick part ;
a first electrode provided on the first thick part; and
a second electrode electrically connected to the second semiconductor layer.

2. The device according to claim 1, wherein a maximum width of the second thick part orthogonal to a direction of the extension is smaller than a minimum width of the first thick part in a plane parallel to the first major surface.

3. The device according to claim 1, wherein
the stacked body has a rectangular shape with a long side and a short side, in a planar view parallel to the first major surface,
a longitudinal direction of the first thick part corresponds to a direction along the short-side of the rectangular shape, and
a longitudinal direction of the second thick part corresponds to a direction along the long-side of the rectangular shape.

4. The device according to claim 1, wherein
the stacked body has a shape of a rectangular shape with a long side and a short side, in a planar view parallel to the first major surface,
the first thick part is provided in a region including a center of the rectangular shape, and
the second thick part extends from the first thick part in a long-side direction and in a short-side direction of the rectangular shape.

5. The device according to claim 1, wherein
the stacked body has a rectangular shape with a long side and a short side, in a planar view parallel to the first major surface,
the first thick part has a region including a center of the rectangular shape and has a portion extending along the long-side from the region including the center of the rectangular shape, and
the second thick part has a portion extending along the short side from the region of the first thick part including the center of the rectangular shape, and has a portion extending along the short-side from the portion of the first thick part extending along the long-side of the rectangular shape.

6. The device according to claim 1, wherein the stacked body is provided on a substrate in sequence of the second semiconductor layer, the light emitting layer and the first semiconductor layer.

7. The device according to claim 6, wherein the substrate is one of a sapphire substrate, a silicon substrate, an SIC substrate, and a GaN substrate.

8. The device according to claim 6, wherein the first semiconductor layer includes an carrier block layer provided on a side of the light emitting layer for preventing electrons from overflowing from the light emitting layer, and a contact layer of a first conductivity type provided on a side of the transparent electrode.

9. The device according to claim 1, wherein the second electrode is provided on a second major surface of the stacked body on a side of the second semiconductor layer and reflects light emitted from the light emitting layer.

10. The device according to claim 9, wherein the second electrode includes a multilayer film containing at least one of silver (Ag) and gold (Au).

11. The device according to claim 9, further comprising a current blocking layer provided between the second electrode and the second semiconductor layer to block a current flowing between the transparent electrode and the second electrode, wherein the second thick part has a portion not overlapping the current blocking layer, in a planar view parallel to the first major surface.

12. The device according to claim 11, wherein the current blocking layer includes a silicon oxide film.

13. The device according to claim 11, wherein the current blocking layer is provided under the first electrode, in a planar view parallel to the first major surface.

14. The device according to claim 9, further comprising a support substrate on a side of the second semiconductor layer, wherein the second semiconductor layer is provided between the support substrate and the light emitting layer.

15. The device according to claim 1, wherein a thickness of the first thick part and a thickness of the second thick part are the same.

16. The device according to claim 1, wherein a thickness of the thin part is not more than ½ of a thickness of the second thick part.

17. The device according to claim 1, wherein the transparent electrode is provided inside an outer edge of the first major surface.

18. The device according to claim 1, wherein the transparent electrode contains at least one of ITO, ZnO, and Sn₂O.

19. The device according to claim 1, wherein the light emitting layer includes a multiple quantum well in which well layers and barrier layers are alternately stacked.

20. The device according to claim 1, wherein the first electrode includes a multilayer film containing nickel (Ni) and gold (Au)
